(19) United States
(12) Patent Application Publication
(10) Pub. No.: US 2007/0171100 A1
(43) Pub. Date: Jul. 26, 2007

(54) CONTROL CIRCUIT FOR 2 STAGE CONVERTER

(75) Inventors: David New, Arlington, TN (US); George Schuellein, Narragansett, RI (US)

Correspondence Address: OSTROLENK FABER GERB & SOFFEN, 1180 AVENUE OF THE AMERICAS, NEW YORK, NY, 100368403, US

(73) Assignee: INTERNATIONAL RECTIFIER CORPORATION, El Segundo, CA (US)

(21) Appl. No.: 11/563,406

(22) Filed: Nov. 27, 2006

Related U.S. Application Data
(60) Provisional application No. 60/740,008, filed on Nov. 28, 2005.

(51) Int. Cl. H03M 7/00

(52) U.S. Cl. 341/50

(57) ABSTRACT

A multi-stage voltage converter in accordance with an embodiment of the present invention includes a first stage converter operable to convert an input voltage into a first output voltage, at least one second stage converter operable to receive the first output voltage from the first stage converter and to provide a second output voltage and a control circuit operable to control both the first stage converter and the second stage converter. The control circuit may independently control the first stage converter and the second stage converter using closed loop feedback. Alternatively, the control circuit may control the first stage converter such that the first stage converter has a constant duty cycle. In another embodiment, the control circuit may control the first stage converter such that the first stage converter has a duty cycle that follows the duty cycle of the second stage converter.

### CROSS REFERENCE TO RELATED APPLICATIONS

The present application claims the benefit of and priority to U.S. Provisional Patent Application Ser. No. 60/740,008 entitled CONTROL TECHNIQUE FOR 2 STAGE CONVERTERS, filed Nov. 28, 2005, the entire contents of which are hereby incorporated by reference herein.

The present application is also related to U.S. patent application Ser. No. 11/551,054 entitled MULTIPLE OUTPUT CONVERTER AND CONTROL IC filed Oct. 19, 2006 which claims benefit of U.S. Provisional Patent Application Ser. No. 60/731,206 entitled MULTI-OUTPUT CONVERTER CONTROL IC, filed on Oct. 28, 2005, the entire contents of both of which are hereby incorporated by reference herein.

### BACKGROUND OF THE INVENTION

Multi-phase interleaved buck-converters are commonly used as voltage regulators in computer motherboards. These multi-phase converters typically include several sync-buck converters connected in parallel, that are phase shifted. The converters typically convert a 12V input to provide approximately 1.3 V and at least 100 A to the CPU socket.

The recent and ongoing trend of increasing CPU clock speeds has, in turn, resulted in increases in the current required by CPU's and an increase in the slew rate requirements of the CPU socket. In the meantime, generally, CPU voltage requirements have decreased while voltage inputs have risen from approximately 5V in the past, to the common 12 V inputs noted above. Naturally, voltage regulators have developed over time to accommodate these changing needs. That is, additional phases have been added in order to allow for the provision of addition current and additional output capacitors have been added to provide for the necessary slew rate. In addition the duty cycle of the converters has decreased. As a result, the converters have become less efficient and have required more board space in order to accommodate the additional phases and capacitors mentioned above.

One solution to these problems is the use of a two-stage converter, or other multi-stage converter. In such multi-stage converters, a single or multi-phase sync-buck converter is provided in a first stage and is connected in series with a multi-phase sync-buck converter in a second stage. The first stage typically steps down the input voltage and typically has a relatively low switching frequency, and thus, is relatively efficient. The second stage takes this lower voltage as an input and its output supplies the CPU socket. The second stage typically is switched at a high frequency. This higher frequency does not pose a problem in light of the relatively low input bus voltage that is supplied to the second stage from the first stage. The use of this lower voltage reduces switching losses at the higher frequency of the second stage. The higher frequency of the switching in the second stage also allows for a decrease in the necessary filters at the output. Smaller inductors and a reduced number of output capacitors thus result in savings in component count, board space and cost. In addition the high frequency allows for increased bandwidth.

In the past, such multi-stage controllers were operated with the first stage in closed loop while the second stage used an additional independent closed loop controller. While this solution provides good results, it also requires the use of two separate control ICs.

Thus, it would be beneficial to provide a multi-stage voltage converter that utilizes a single control circuit, preferably an IC to control both a first stage and a second stage of the converter.

### SUMMARY OF THE INVENTION

It is an object of the present invention to provide a multi-stage converter that provides higher efficiency, lower expense and otherwise avoids the problems described above.

A multi-stage voltage converter in accordance with an embodiment of the present invention includes a first stage converter operable to convert an input voltage into a first output voltage, at least one second stage converter operable to receive the first output voltage from the first stage converter and to provide a second output voltage and a control circuit provided in a single package operable to control both the first stage converter and the second stage converter.

A multi-stage voltage converter in accordance with another embodiment of the present invention includes a first stage converter operable to convert an input voltage into a first output voltage, at least one second stage converter operable to receive the first output voltage from the first stage converter and to provide a second output voltage and a control circuit operable to control both the first stage converter and the second stage converter, wherein the control circuit controls the first stage converter such that the duty cycle of the first stage converter remains constant.

A multi-stage voltage converter in accordance with another embodiment of the present invention includes a first stage converter operable to convert an input voltage into a first output voltage, at least one second stage converter operable to receive the first output voltage from the first stage converter and to provide a second output voltage and a control circuit operable to control both the first stage converter and the second stage converter, wherein the control circuit controls the first stage converter such that the duty cycle of the first stage converter follows a duty cycle of the second stage converter.

Other features and advantages of the present invention will become apparent from the following description of the invention which refers to the accompanying drawings.

### BRIEF DESCRIPTION OF THE DRAWING(S)

FIG. 1 is an illustration of a control integrated circuit for a multi-stage voltage controller in accordance with an embodiment of the present application.

FIG. 2 is an illustration of a control integrated circuit for a multi-stage voltage controller in accordance with another embodiment of the present application.

FIG. 3 is an illustration of a control integrated circuit for a multi-stage voltage controller in accordance with another embodiment of the present application.

FIG. 4 is an illustration of a multi-stage converter utilizing the control integrated circuit of FIG. 1 in accordance with an embodiment of the invention.

FIG. 5 is an illustration of a multi-stage converter utilizing the control integrated circuit of FIG. 2, in accordance with an embodiment of the present invention.

FIG. 6 is an illustration of a multi-stage converter utilizing the control integrated circuit of FIG. 3 in accordance with an embodiment of the invention.

FIG. 7 illustrates a multiple output control circuit in accordance with and embodiment of the present invention.

FIG. 8 illustrates a single stage voltage converter utilizing the control circuit of FIG. 7 in accordance with an embodiment of the present invention.

FIG. 9 illustrates a multi-stage voltage converter utilizing the control circuit of FIG. 7 in accordance with an embodiment of the present invention.

### DETAILED DESCRIPTION OF PREFERRED EMBODIMENTS OF THE INVENTION

A multi-stage converter in accordance with a an embodiment of the present application preferably includes a control circuit for control of each of the first and second stages (and additional stages if provided) of the multi-stage converter in one integrated circuit. As noted above, it is common to control such multi-stage converters in a closed loop fashion by providing a closed loop controller for the first stage and a separated closed loop controller for the second stage. As noted above, however, this is inefficient as it typically requires the use of two controller ICs.

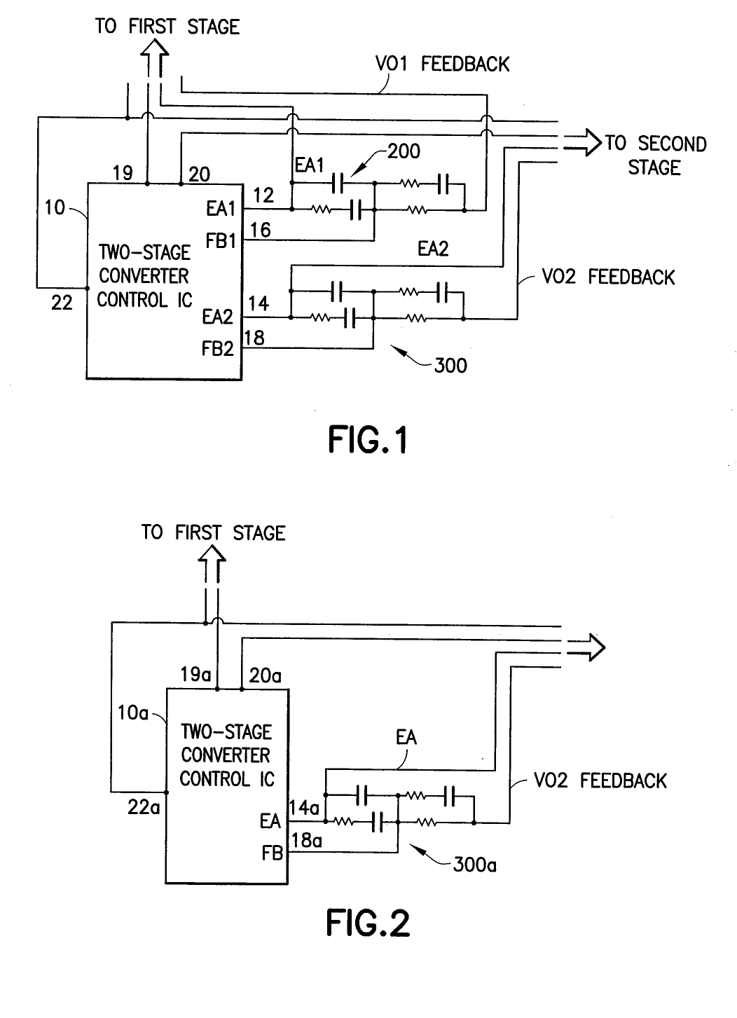

FIGS. 1-3 illustrate three examples of a control IC in accordance with the present invention that provide for control of both the first stage and the second stage of a multi-stage converter in a single integrated circuit. The ICs are illustrated in FIGS. 1-3 without the associated PWM and driver circuitry that would typically be used in conjunction with them.

FIG. 1 illustrates a control IC 10 that utilizes a so-called Independent/Independent topology. As can be seen in FIG. 1, the IC 10 includes error amplifier (EA) outputs 12, 14 for each stage of a two stage controller and also includes feedback (FB) inputs 16, 18 from each of the stages. Clock frequency outputs 19, 20 for the two stages are also provided. In addition, biasing and reference information may be provided to the driver circuitry used to drive the first and second stages via the biasing and reference output 22. Further, a compensation network 200 for the first stage and a compensation network 300 for the second stage are also shown. The compensation network 200 of the stage receives the first output voltage VO1 of the first stage and provides feedback information to the feedback input 16. This information is also used to generate the first error amplifier output signal provided on the first error amplifier output 12. Similarly, compensation network 300 for the second stage received the second output voltage VO2 from the second stage of the converter and provides feedback information to the second feedback input 18. This information is also used to generate a second error amplifier output signal from the second error amplifier output 14.

FIG. 2 illustrates another example of a control integrated circuit 10a, that uses a Fixed Duty Cycle/Independent topology to control both the first and second stages of a multi-stage controller. As illustrated in FIG. 2, the IC 10a includes a single error amplifier output 14a for the second stage and a single feedback input 18a from the second stage. The first stage has a constant duty cycle, so there is no error amplifier output or feedback for the first stage. The control IC 10a however also includes two frequency outputs 19a, 20a for the first stage and second stage, respectively. Biasing and reference information may be provided to the driver circuitry used to drive the first and second stages via the biasing and reference output 22a. The compensation circuit 300a for the second stage operates in substantially the same manner as the compensation circuit 300 described above. It is noted that in this embodiment the compensation circuit for the first stage is not necessary.

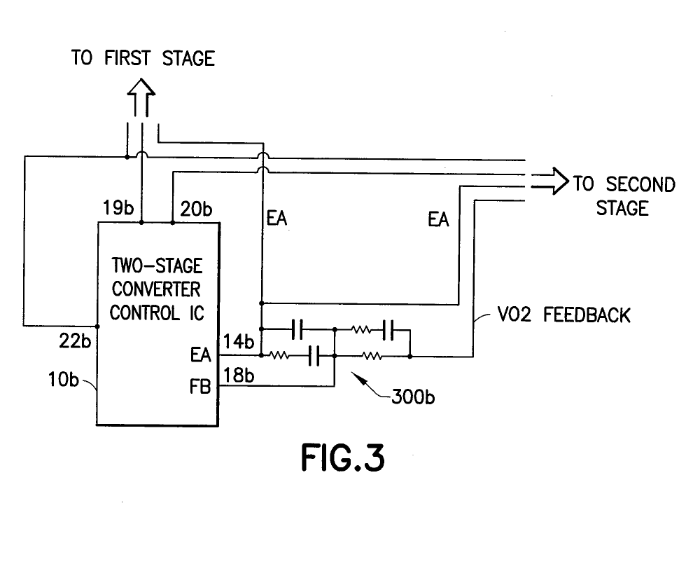

FIG. 3 illustrates another example of a control IC 10b that uses Slave/Dependent topology to control the two stages of a multi-stage converter. The control IC 10b provides a single error amplifier output 12b that is provided to both the first stage and the second stage. The control IC 10b also includes a feedback input 18b from the second stage and two frequency outputs 19b, 20b for the first stage and second stage, respectively. Biasing and reference information may be provided to the driver circuitry used to drive the first and second stages via the biasing and reference output 22b. The compensation circuit 300b operates in a similar manner as the compensation circuit 300 described above. Again, a compensation circuit for the first stage is not utilized in this embodiment.

The control ICs 10, 10a and 10b are connected to the first stage and second stage in order to provide appropriate control signals. The control ICs preferably provide a frequency output to each of the first and second stages. These two frequency signals may be obtained in different ways. One solution is to provide two oscillators and thus ensure that the two frequency signals are independent of each other. Another solution is to set the switching frequency of one of the first or second stages to be a multiple of the switching frequency of the other stage, thus requiring only one oscillator.

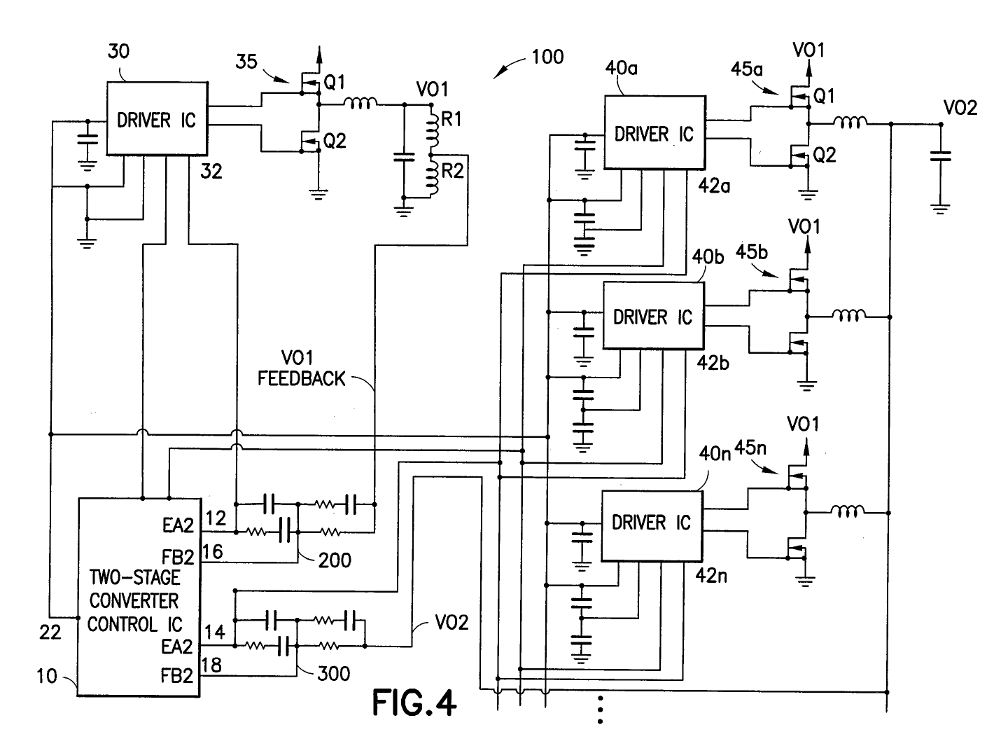

FIGS. 4-6 illustrate exemplary embodiments of multi-stage converters that utilize the three respective control ICs 10, 10a and 10b. FIG. 4 illustrates a multistage converter 100 with the control IC 10 connected to a first stage driver 30 and a plurality of second stage drivers 40a, 40b, 40n. The driver 30 drives the first stage conversion device 35, that is, switches Q1,Q2, to provide the output voltage VO1. The drivers 40a, 40b, 40n are similarly used to drive the second stage conversion devices 45a, 45b, 45n. As illustrated, the output voltage VO1 is provided to control IC 10 as a feedback signal via a resistor divider formed by resistors R1, R2. It is noted however, that the first output voltage VO1 need not be provided in this manner. The output voltage VO1 is provided to the compensation network 200 of the first stage, which is, in turn, connected to the feedback input 16 and the error amplifier output 12 of the IC 10 and to the error amplifier input 32 of the first stage driver IC 30. Thus, the first stage driver 30 is controlled based on a closed loop architecture that utilizes the output voltage VO1 to adjust the frequency and error signal provided to the driver 30. Such a closed loop system is well known in the art and thus need not be discussed in further detail herein.

The output voltage VO2 of the second stage is similarly connected to the compensation network 300 for the second stage which is in turn connected to the feedback input 18. The error amplifier output 14 of the IC 10 is connected to the error amplifier inputs 42a, 42b, 42n of the drivers 40a, 40b, 40n for the second stage. The drivers are used to drive the conversion devices 45a, 45b, 45n which provide the second output voltage VO2. It is noted that the output voltage VO1 of the first stage is used as an input to the second stage conversion devices 45a, 45b, 45n. Appropriate biasing and reference information is also provided to the driver 30 and the drivers 40a-40n via the biasing and reference output 22. Thus, the drivers 40a, 40b, 40n of the second stage are similarly controlled using a closed loop architecture such that the output voltage VO2 provides feedback to control the error signal provided to the drivers 40a to 40n to control the second stage converters. Thus, in FIG. 4, a single IC control circuit 10 is used to provide closed loop control to both the first stage and second stage of the voltage converter 100. It is noted that the closed loop control provided to the first stage is independent from that provided to the second stage, thus this approach is referred to as Independent/Independent topology.

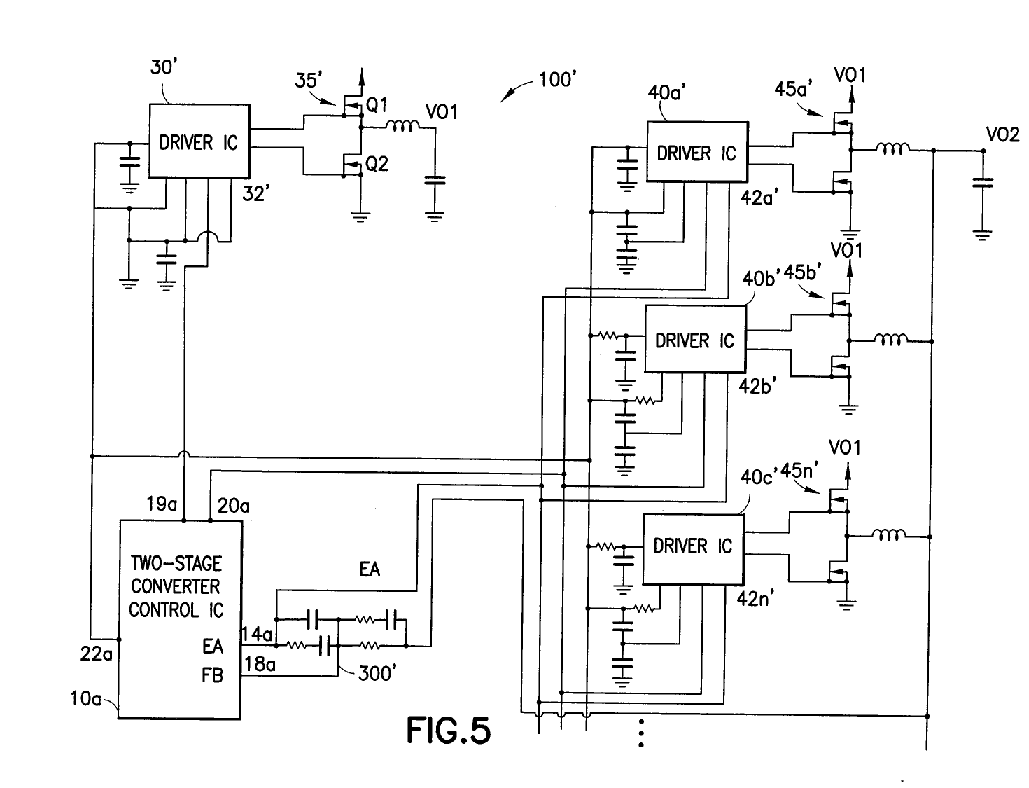

FIG. 5 illustrates another example of a multistage converter 100′ that utilizes the control IC 10a. The control IC 10a is connected to first stage driver 30′ which drives first stage conversion device 35′ and a plurality of second stage drivers 40a′, 40b′, 40n′ that drive the second stage conversion devices 45a′, 45b′, 45n′. In this exemplary circuit, the driver 30′ operates at a constant duty cycle. The error amplifier input 32′ is connected to the biasing and reference output 22′ of the IC 10a and the constant clock frequency output is provided to the driver 30′ from control IC 10a. The output voltage of the second stage VO2′, however, is connected to the compensation network 300′ for the second stage which is in turn connected to the feedback input 18a. The error amplifier output 14a of the IC 10a is connected to the error amplifier inputs 42a′, 42b′, 42n′ of the drivers 40a′, 40b′, 40n′ for the second stage. The biasing and reference information is also provided to the driver 30′ and the drivers 40a′-40n′ via the biasing and reference output 22′. Thus, the circuit of FIG. 5 provides a single integrated circuit controller 10a that controls the first stage at a constant frequency and duty cycle and the second stage in a closed loop fashion. The first stage conversion device 35′ is used to step down the input voltage to the voltage VO1, but this voltage VO1 need not be tightly controlled.

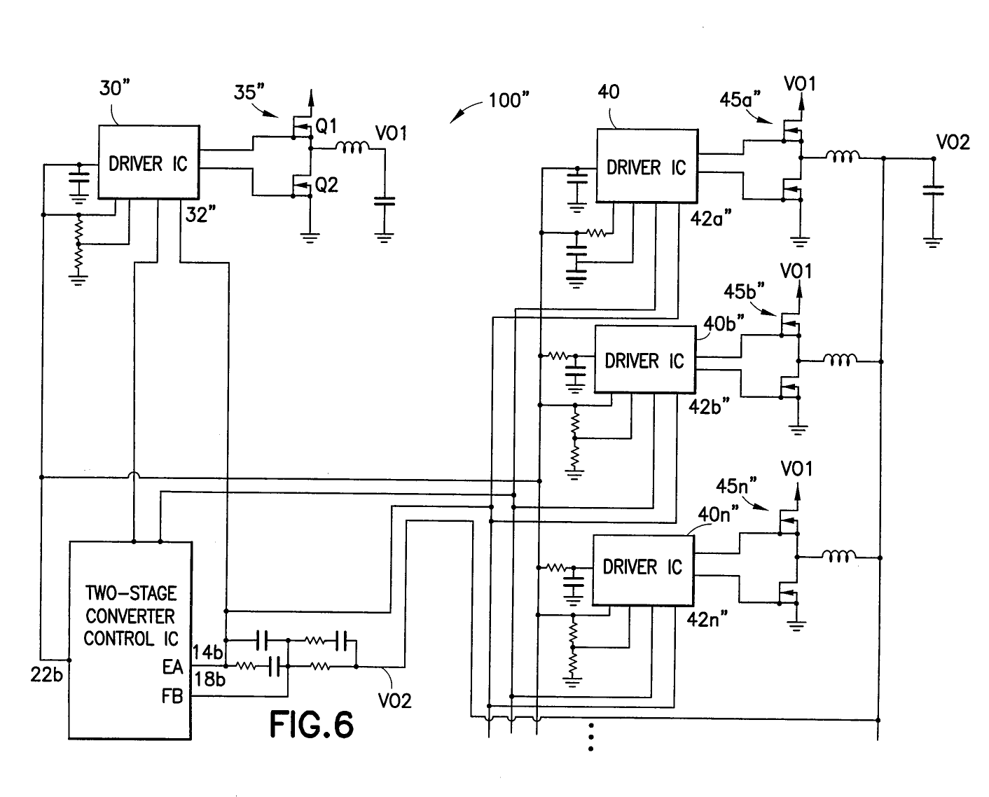

FIG. 6 illustrates a multistage converter 100″ that utilizes the control IC 10b of FIG. 3 which is connected to first stage driver 30″ and a plurality of second stage drivers 40a″, 40b″, 40n″. In this exemplary circuit, the first stage driver 30″ will operate at the same duty cycle as the second stage drivers 40a″-40n″. The output voltage VO2″ of the second stage is provided as feedback to the compensation network 300″ for the second stage which is, in turn, connected to the feedback input 18b. The error amplifier output 14b of the IC 10b is provided to the error amplifier inputs 42a″, 42b″, 042n″ of the drivers 40a″, 40b″, 40n″ for the second stage and the error amplifier inputs of the driver 30″. The appropriate biasing and reference information is also provided to the driver 30″ and the drivers 40a″-40n″ via the biasing and reference output 22″. Thus, in the circuit of FIG. 6, the first stage converter is controlled based on the information provided by the closed loop information of the second stage. That is, the same error amplifier output signal is provided to the error input 32″ of the driver 30″ as is provided to the error inputs 42a″, 42b″, 42n″ of the second stage drivers based on the feedback from the second stage output voltage VO2.

In FIGS. 4-6, the first stage is shown powering a single multi-phase output. However, a two stage converter with multiple outputs (or, a single stage converter with multiple outputs) may be provided. In this case, the first stage would supply a bus voltage, or input voltage, to the inputs of the second stage converter. Each output of the second stage would then serves the requirements of its particular system.

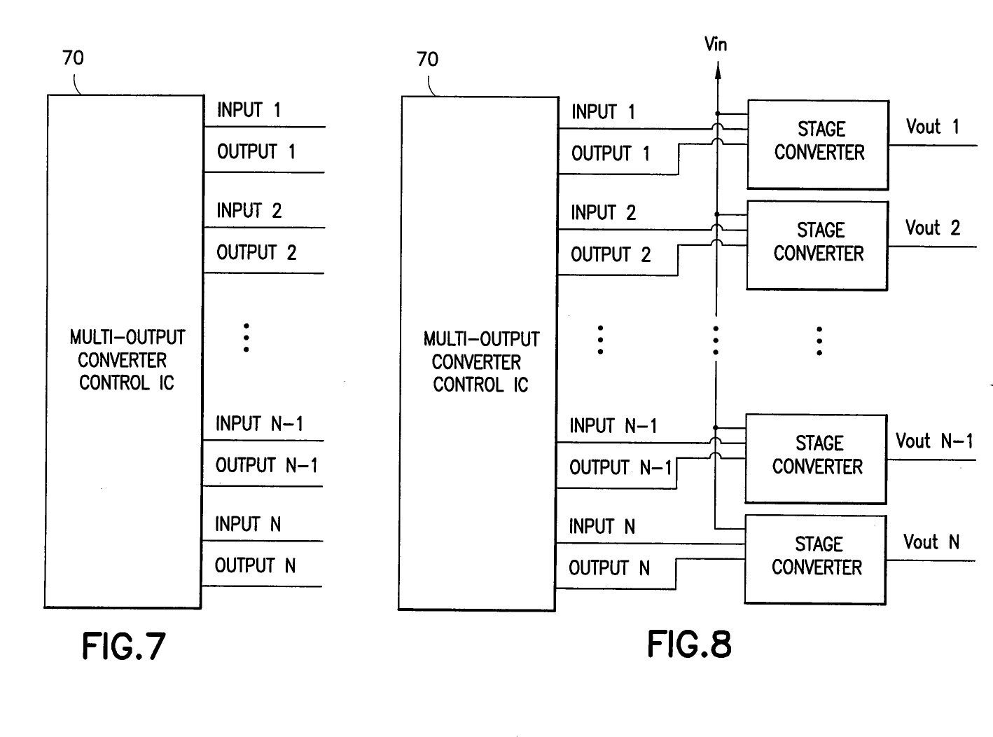

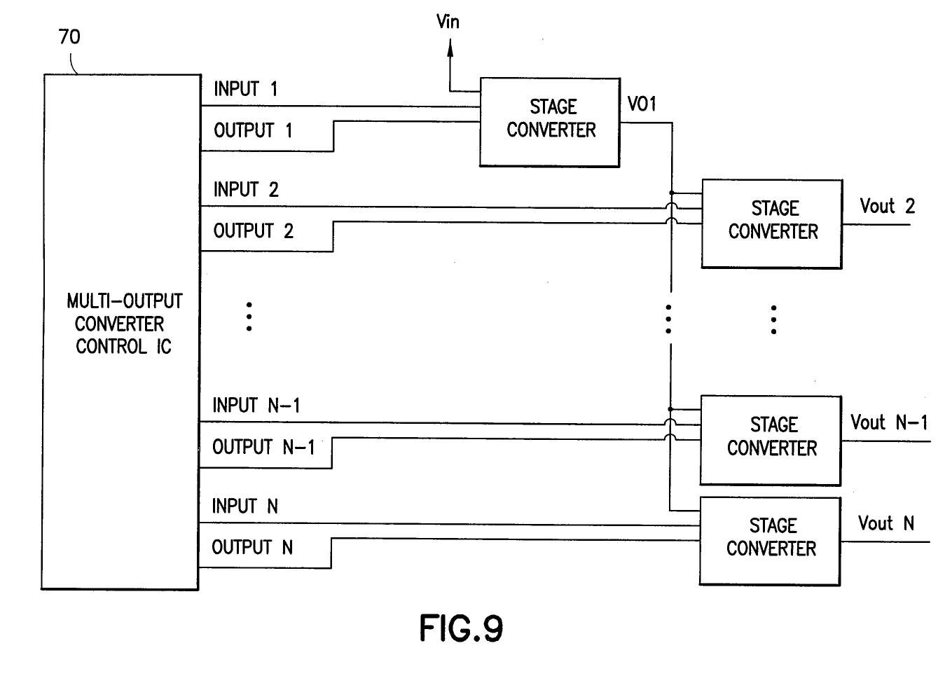

FIG. 7 illustrates the idea of a multi-output control IC 70. In FIG. 7, the pins of the IC and their functionality are generalized. FIG. 7 shows N sets of input/output pairs (Input1/Output1, Input2/Output2 . . . InputN/OutputN). In this generalize representation, each input output pair serves the requirements of a “stage” converter. This “stage” converter may be a single-phase or multi-phase converter. The “stage” inputs and outputs are very versatile in that they may be used for single-stage converters (as illustrated in FIG. 8) or multi-stage converters (as shown in FIG. 9).

The control scheme for the multi-output control IC has many possibilities. All or some of the input/output pairs may be configured so that each “stage” converter will operate closed-loop with the remainder of the “stage” converters operating in fixed duty cycle or in a slave configuration as described above. In FIGS. 7-9 the control capabilities of the IC and the configuration of each “stage” converter is generalized.

Further, it is noted that in FIGS. 7-9 the control IC and the drivers are not shown separately as in FIGS. 4-6. The integration of the driver and control functionality for any of the control ICs described herein is possible if the details of design suggest that need. The concept of providing a voltage converter with multiple output voltages is described in detail U.S. patent application Ser. No. 11/551,054 entitled MULTIPLE OUTPUT CONVERTER AND CONTROL IC filed Oct. 19, 2006. In accordance with this system, the output of each of the second stage conversion devices could be used to provide power to a different load or subsystem.

The present application identifies additional methods to control the operation of a two stage converter's first stage. Previous methods disclosed controlling both stages using closed loop feedback. However, in accordance with the present invention, the cost and die size required by the control IC to implement the Fixed Duty Cycle and Slave configurations described above will be less that for a closed-loop controller. Both the Fixed Duty Cycle and Slave configurations allow for control of the first stage while reducing the number of passive components needed around the control IC.

Further, the control circuits of the present invention reduce the number of control ICs necessary and thus simplify design. In addition, the present invention reduces overall die cost since a less expensive two-stage controller die with a smaller area than two conventional controller dies may be used. Further, in accordance with the present invention, it is possible to combine certain common IC features/functionality that would otherwise have been duplicated by two ICs. In addition, as noted above, the present invention allows for a reduction in the number of passive components around the control IC since the number of control ICs has been reduced and common IC features and functionality are combined. In addition, the present invention allows for a reduction in board area since fewer ICs and passive components are necessary. Further, it is noted that the Slave/Independent topology may provided reduced bus capacitance when compared to that of the Fixed Duty Cycle/Independent topology.

In addition, as noted above, the present invention is applicable to multi-output control ICs. These ICs are very versatile in that they allow the designer the choice of single- or multi-stage converter configurations, multi-phase and conventional single phase operation and a variety of control topologies for the system.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A multi-stage voltage converter comprising:
a first stage converter operable to convert an input voltage into a first output voltage;
at least one second stage converter operable to receive the first output voltage from the first stage converter and to provide a second output voltage; and
a control circuit provided in a single package operable to control both the first stage converter and the second stage converter.

2. The multi-stage converter of claim 1, wherein the control circuit is configured to provide a first clock frequency signal to the first stage converter to set a switching frequency of the first stage converter and to provide a second clock frequency signal to the at least one second stage converter to set a switching frequency of at least the second stage converter.

3. The multi-stage converter of claim 2, wherein the control circuit is configured to provide a first error amplifier output signal to the first stage converter to set a duty cycle of the first stage converter and to provide a second error amplifier output signal to the at least one second stage converter to set a duty cycle of at least the second stage converter.

4. The multi-stage converter of claim 3, wherein the control circuit is configured to provide a biasing and reference signal to both the first and second stage converters to set biasing and reference value information for the first stage converter and the second stage converter.

5. The multi-stage converter of claim 4, further comprising;
a second stage feedback circuit configured to receive the second output voltage and to provide a second feedback input to the control circuit for use in providing the second error amplifier output signal.

6. The multi-stage converter of claim 5, further comprising:
a first stage feedback circuit configured to receive the first output voltage and to provide a first feedback input to the control circuit for use in providing the first error amplifier output signal.

7. The multi-stage converter of claim 6, wherein the duty cycle of the first stage converter is set by the first error amplifier output signal of the control circuit and the duty cycle of the second stage converter is set based on the second error amplifier output signal, wherein the first error amplifier output signal and second error amplifier output signal are independent of each other.

8. The multi-stage converter of claim 5, wherein the duty cycle of the first stage converter is substantially fixed and the duty cycle of the second stage converter is set based on the second error amplifier output signal.

9. The multi-stage converter of claim 5, wherein the duty cycle of the first stage converter and the duty cycle of the second stage converter are both set based on the second error amplifier output signal such that the duty cycle of the first stage converter is substantially the same as the duty cycle of the second stage converter.

10. The multi-stage converter of claim 9, wherein the control circuit is a single integrated circuit.

11. The multi-stage converter of claim 7, wherein the control circuit is a single integrated circuit.

12. The multi-stage converter of claim 7, wherein the second stage converter is a multi-phase converter.

13. The multi-stage converter of claim 1, wherein the first stage converter is a single or multi-phase converter.

14. The multi-stage converter of claim 13, wherein the second stage converter is a single or multi-phase converter.

15. The multi-stage converter of claim 8, wherein the second stage converter is a multi-phase converter.

16. The multi-stage converter of claim 9, wherein the second stage converter is a multi-phase converter.

17. A multi-stage voltage converter comprising:
a first stage converter operable to convert an input voltage into a first output voltage;
at least one second stage converter operable to receive the first output voltage from the first stage converter and to provide a second output voltage; and
a control circuit operable to control both the first stage converter and the second stage converter, wherein the control circuit controls the first stage converter such that the duty cycle of the first stage converter remains constant.

18. A multi-stage voltage converter comprising:
a first stage converter operable to convert an input voltage into a first output voltage;
at least one second stage converter operable to receive the first output voltage from the first stage converter and to provide a second output voltage; and
a control circuit operable to control both the first stage converter and the second stage converter, wherein the control circuit controls the first stage converter such that the duty cycle of the first stage converter follows a duty cycle of the second stage converter.
